(19) United States
(12) Patent Application Publication
(10) Pub. No.: US 2012/0043970 A1
(43) Pub. Date: Feb. 23, 2012

(54) Automatic Tuning of a Capacitive Sensing Device

(75) Inventor: Dana Olson, Kirkland, WA (US)

(73) Assignee: CYPRESS SEMICONDUCTOR CORPORATION, San Jose, CA (US)

(21) Appl. No.: 12/618,661

(22) Filed: Nov. 13, 2009

Related U.S. Application Data
(60) Provisional application No. 61/114,374, filed on Nov. 13, 2008.

(51) Int. Cl. G01R 27/26; G01R 35/00

(52) U.S. Cl. 324/601; 324/686; 324/679

(57) ABSTRACT

An apparatus, system and method for automatically tuning a capacitance sensor based on comparisons of measured capacitance values to expected values and ranges of values is described. Measured capacitance is converted to a digital value with a capacitance to digital converter. The digital value is use to adjust the range, resolution, baseline offset and thresholds of the capacitance sensor according to logic executed by a controller and stored in programs in a memory.

### CROSS-REFERENCE TO RELATED APPLICATIONS

This application claims the benefit of U.S. Provisional Patent Application No. 61/114,374, filed Nov. 13, 2008.

### TECHNICAL FIELD

This disclosure laces to the field of user interface devices and, in particular, to capacitive sensor devices.

### BACKGROUND

In general, capacitive sensors are intended to replace mechanical buttons, knobs, and other similar mechanical user interface controls. Capacitive sensors allow the elimination of such complicated mechanical controls and provide reliable operation under harsh conditions. Capacitive sensors are also widely used in modern customer applications, providing new user interface options in existing products.

Capacitive sensing systems generally operate by detecting a change in the capacitance of a capacitive sensor resulting from proximity or contact of an object with the sensor. The ability to resolve changes in capacitance may be impaired if the changes in capacitance to be detected by the sensor are small relative to the capacitance of the sensor.

Capacitive sensors may be sensitive to multiple external influences. Board layout, sensor design, routing, and other system components may impact the parasitic capacitance of a sensor. Differences between sensors make configuring and normalizing sensitivity among a plurality of sensors in an array difficult. Noise sources close to sensors or with frequencies that are more easily received by some sensors than others introduce other variables in the configuring of a capacitive sensor during development.

### BRIEF DESCRIPTION OF THE DRAWINGS

The present disclosure is illustrated by way of example, and not by way of limitation, in the figures of the accompanying drawings.

FIG. 1 illustrates an embodiment of a capacitive sensing system according to the present invention.

FIG. 2 illustrates an embodiment of a capacitive sensing system according to the present invention.

FIG. 3 illustrates an embodiment of a capacitive sensing system according to the present invention.

FIG. 4A illustrates an embodiment of a charge transfer capacitive sensing circuit according to the present invention.

FIG. 4B illustrates an embodiment of a charge transfer capacitive sensing circuit according to the present invention,

FIG. 5 illustrates an embodiment of a method for automatically tuning a capacitive sensing system according to the present invention.

FIG. 6 illustrates an embodiment of a method for setting range parameters according to the present invention.

FIG. 7 illustrates an embodiment of a method for detecting maximum signals according to the present invention.

FIG. 8 illustrates an embodiment of a method for calculating the noise on the output of the capacitance to digital converter according to the present invention.

### DETAILED DESCRIPTION

Described in embodiments herein area method and apparatus for automatically tuning a capacitance sensor. The following description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format. Particular implementations may vary from these exemplary details and still he contemplated to be within the spirit and scope of the present invention.

Embodiments of a method and apparatus for automatically tuning and configuring a capacitive sensor are described. In one embodiment, a capacitance to code converter includes capacitance sensing circuitry that measures changes in the capacitance C_{X} of the capacitive sensor and generates a digital output with a value based on the measured capacitance C_{X}. Changes in the capacitance C_{X} of the capacitive sensor may be caused by inputs, such as a finger or other object in proximity or in contact with the capacitive sensor. These changes are reflected in the digital output, which can be processed by a computer system or other circuit.

In one embodiment, the capacitance sensing circuitry has several parameters that can be manipulated to change the output of the capacitance sensing circuitry with no input in proximity or in contact with the capacitance sensor or with an input in proximity or contact with the capacitance sensor. The digital output from the capacitance sensing circuitry may have parameters that adjust such variables as such as range, resolution, offset, and a variety of thresholds, as described herein.

A description of capacitance sensor physics and construction can be found in U.S. Published application Ser. No. 11/600,255 (U.S. Published Application 2008/0111714) which is incorporated herein by reference.

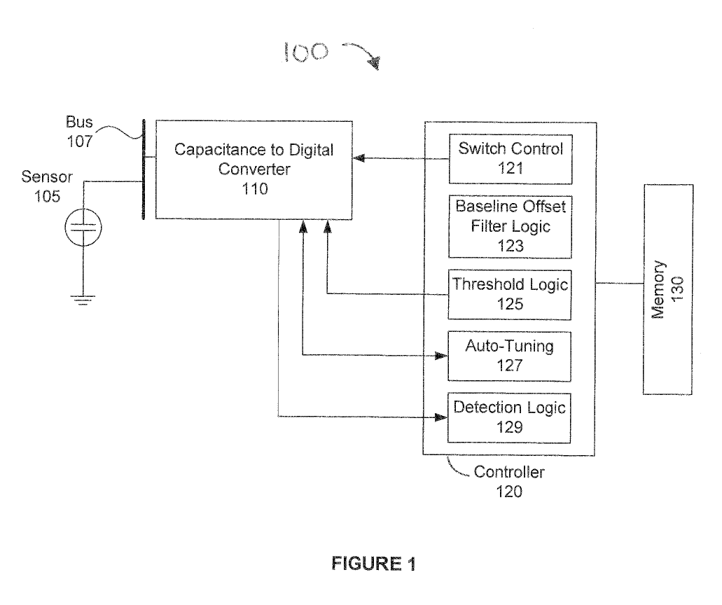

FIG. 1 illustrates a block diagram of one embodiment of an electronic system in which a capacitance to digital converter with auto tuning logic can be implemented. Electronic system 100 includes a sensor 105 coupled to capacitance to digital converter 110. In one embodiment, there may only be one sensor. In another embodiment, there may be multiple sensors coupled to the capacitance to digital converter 110 simultaneously or at different times. The capacitance to digital converter 110 is coupled to controller 120, which is coupled to memory 130. The controller 120 comprises several control and logic elements including: switch control 121, baseline offset filter logic 123, threshold logic 125, auto tuning logic 127 and detection logic 129. Switch control 121 is coupled to the capacitance to digital converter 110 to control the frequency and duty cycle of switches in the capacitance to digital converter and the switching 123 of the capacitance to digital converter between multiple sensors if present. Baseline offset filter logic tracks the output of the capacitance to digital converter and compares that output to previous output measurements. This process can be found in detail in application Ser. No. 11/512,042 (U.S. Published Application 2008/0047764) which is incorporated herein by reference. Threshold logic 125 is coupled to the capacitance to digital converter 110 and to memory 130 and is used by the baseline offset and filter logic 123 to adjust sensing parameters and calculate thresholds. Auto tuning logic 127 is coupled to the capacitance to digital converter 110 and memory 130 and uses baseline offset filter logic and threshold logic 125 by comparing and updating thresholds to baseline offsets. Detection logic is coupled to the capacitance to digital converter 110 and memory 130 and uses baseline offset filter logic 123 and threshold logic 125 by comparing measured values from the capacitance to digital converter 110 to values stored in memory 130.

The capacitance to digital converter 110 may be any capacitance sensing method including charge transfer (described in U.S. Pat. No. 5,703,165), relaxation oscillator (described in U.S. application Ser. No. 11/502,267, now Published Application 20080036473, herein incorporated by reference), sigma-delta modulation (described in U.S. patent application Ser. No. 11/600,255, now Published Application 20080111714, herein incorporated by reference), successive approximation (described in U.S. Pat. No. 7,312,616, herein incorporated by reference), differential charge sharing (described in U.S. Pat. No. 5,374,787), TX-RX (described in U.S. patent application Ser. No. 12/395,462, herein incorporated by reference) or any other such method that converts a capacitance into a digital value. Sensor 105 may be a single sensor or may be representative of a plurality of sensors coupled to the capacitance to digital converter 110 in unison or at different times. Sensor 105 may be coupled to capacitance to digital converter directly Or it may be coupled to capacitance to digital converter 110 through a bus 107. In the case where there is a plurality of sensors, these sensors may be coupled to bus 107 mutually exclusively or in unison.

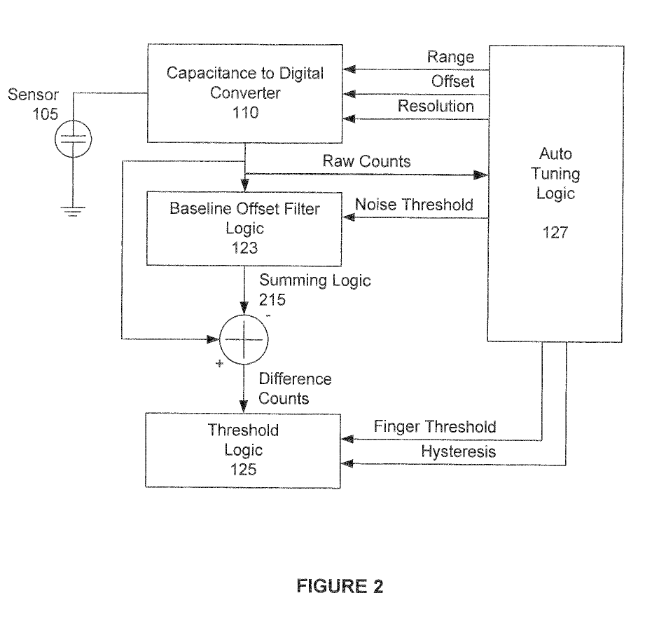

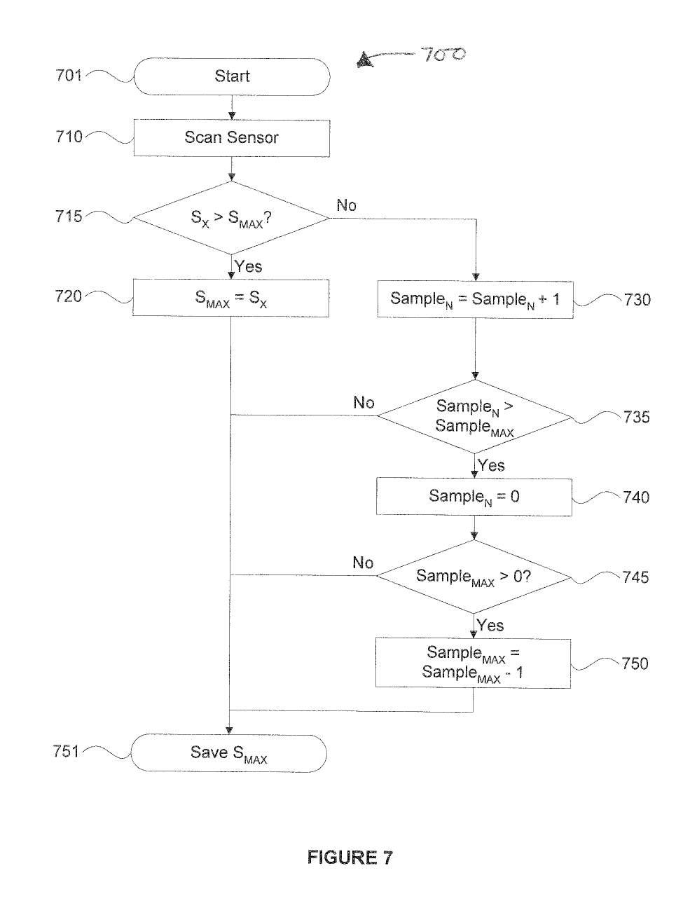

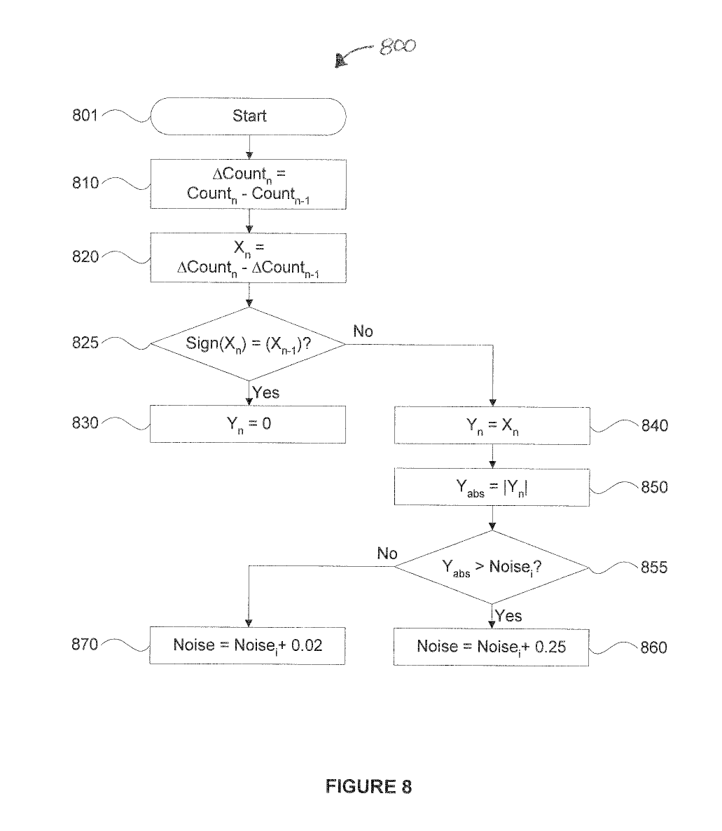

FIG. 2 illustrates the connections between the capacitance to digital converter 110, baseline offset filter logic 123, threshold logic 125, and auto tuning logic 127. Sensor 105 is coupled to capacitance to digital converter 110. Capacitance to digital converter 110 is coupled to baseline offset filter logic 123 and sends the output of the capacitance to digital converter 110 to the baseline offset filter logic 123 to be track the baseline capacitance of the capacitance sensor. The output of capacitance to digital converter 110 is also sent to auto tuning logic 127, which returns signals controlling range, offset and resolution to capacitance to digital converter 110. Auto tuning logic 127 sends noise threshold signals to the baseline offset filter logic 123. Baseline offset filter logic 123 is coupled to threshold logic 125 through summing logic 215 which combines the output of the execution of the baseline offset filter logic 123 and the threshold logic 125. Auto tuning logic 127 is coupled to threshold logic 125 and sends signals on finger threshold (shown in FIG. 7) and hysteresis (shown in FIG. 8) to threshold logic 125.

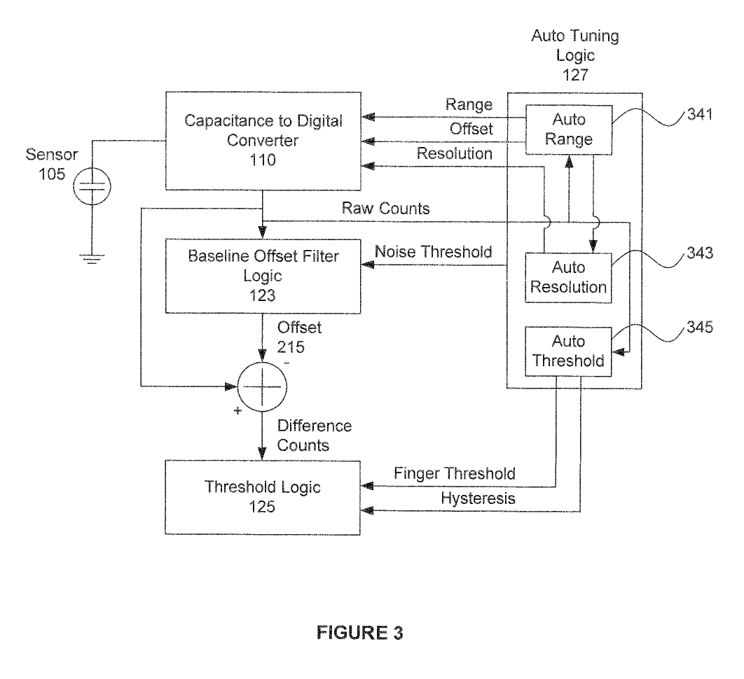

FIG. 3 illustrates the apparatus from FIG. 2 with interconnections of auto tuning logic 127. The auto range function 341 is coupled to the capacitance to digital converter 110 and sends signals “range” and “offset” to the capacitance to digital converter 110. Auto range function 341 uses raw counts from capacitance to digital converter 110 and outputs a range values to the auto resolution function 343 for calibration of resolution parameters. Auto threshold function 345 received raw counts from capacitance to digital converter 110 and is coupled to threshold logic 125 to signals to control “Finger Threshold” (shown in FIG. 7) and “Hysteresis” (shown in FIG. 8).

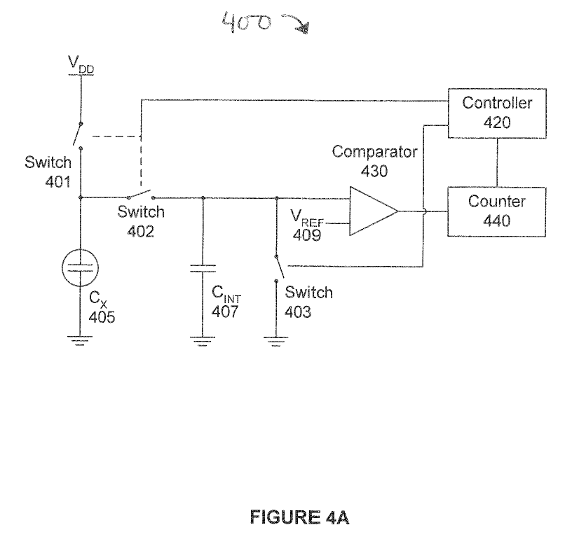

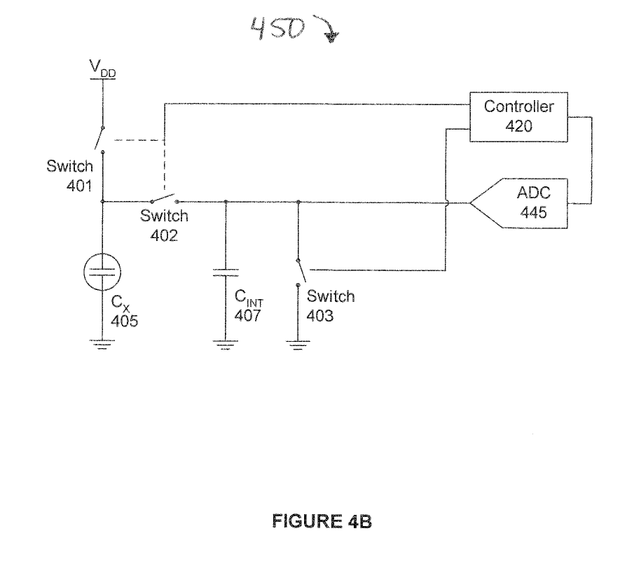

FIG. 4A illustrates an embodiment of a capacitance to digital converter 400. The capacitance to digital converter 400 is a charge transfer measurement circuit. In operation, sensor C_{X} 405 is alternately charged by V_{DD} through switch 401 and discharged to a measurement circuit comprising integration capacitor C_{INT} 407 through switch 402. Switches 401 and 402 may be deadband, break-before-make, switches and are controlled by controller 420. Through repetitious operation of switches 401 and 402, the voltage across C_{INT} 407 increases. The charge transfer circuit is run and a counter 440 is started. When the voltage across C_{INT} 407 reaches a threshold voltage V_{REF} 409 of a comparator 430, the output signal of comparator 430 stops the counter 440 and the value from counter 440 is sent to controller 420. Switch 403 is then closed to reset the voltage on C_{INT} for subsequent measurement cycle. Larger values of C_{X} 405 yield more current flow onto C_{INT} 407 and fewer counts output from counter 440 to controller 420. Possible adjustments for range for this circuit include the value of C_{INT} 407, the switch frequency for switches 401 and 402, and the reference voltage V_{REF} 409. Possible adjustments for resolution include the clock frequency present to counter 440.

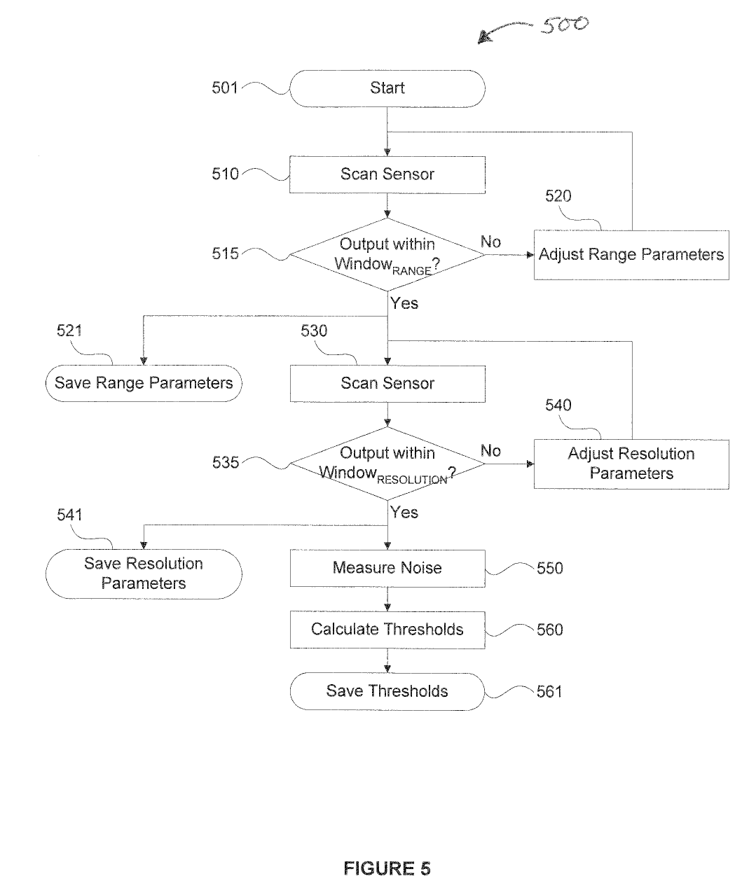

FIG. 4B illustrates an embodiment of a capacitance to digital converter 450. The capacitance to digital converter 450 is a charge transfer measurement circuit. In operation, sensor C_{X} 405 is alternately charged by V_{DD} through switch 401 and discharged to a measurement circuit comprising integration capacitor C_{INT} 407 through switch 402. Switches 401 and 402 may be deadband, break-before-make, switches and controlled by controller 420. Through repetitious operation of switches 401 and 402, the voltage across C_{INT} 407 increases. The charge transfer circuit is run for a determined number of transfer cycles and the voltage across C_{INT} 407 is measured by analog-to-digital converter (ADC) 445. The output of ADC 445 is proportional to the voltage across C_{INT} 407 and is output to controller 420. Switch 403 is then closed to reset the voltage on C_{INT} for subsequent measurement cycle. Larger values of C_{X} 405 yield more current flow onto C_{INT} 407, more voltage across C_{INT} in the measurement time and a high value output by ADC 445. Possible adjustments for range for this circuit 450 include the value of C_{INT} 407 and the switch frequency for switches 401 and 402. Possible adjustments for resolution (shown in FIG. 5) include the resolution of ADC 445. More details on both charge transfer sensing circuits from FIGS. 4A and 4B are in U.S. Pat. No. 7,030,165.

FIG. 5 illustrates a flowchart 500 for the overall method of auto tuning. The auto tuning algorithm is started at block 501. The sensor is scanned in block 510 a capacitance to digital converter such as 110, 400 or 450 and the output of a capacitance to digital converter is compared to a range of expected values (Window_{RANGE}) in decision block 515. If the output of scan sensor block 510 (capacitance to digital converter 110) is not within a Window_{RANGE} of values determined in development, parameters that impact range (such as the switch frequency of switches 401 and 402) are adjusted in block 520 and the sensors are scanned again in block 510. If the value from scan sensor block 510 are within the Window_{RANGE}, (between 25% and 75% of the maximum measurable output of capacitance to digital converter 110, 400 or 450) the range parameters are saved to memory 130 (shown in FIG. 1) in block 521. The sensor is then scanned again in block 530 and the output of capacitance to digital converter 110 is passed to decision block 535 wherein the output of the capacitance to digital converter 110, 400 or 450 is compared to a Window_{RESOLUTION} of values determined in development. If the output of scan sensor block 530 (capacitance to digital converter 110, 400 or 450) is not within a Window_{RESOLUTION} of values determined in development, parameters that impact resolution are adjusted in block 540 and the sensors are scanned again in block 530. If the value from scan sensor block 510 is within the Window_{RESOLUTION}, the range parameters are saved to memory 130 (shown in FIG. 1) in block 541. The noise of the output of capacitance to digital converter 110 is then measured in block 550 (See FIG. 8) and from that noise the thresholds are calculated in block 560. Calculated thresholds are then saved to memory 130 (shown in FIG. 1) in block 561.

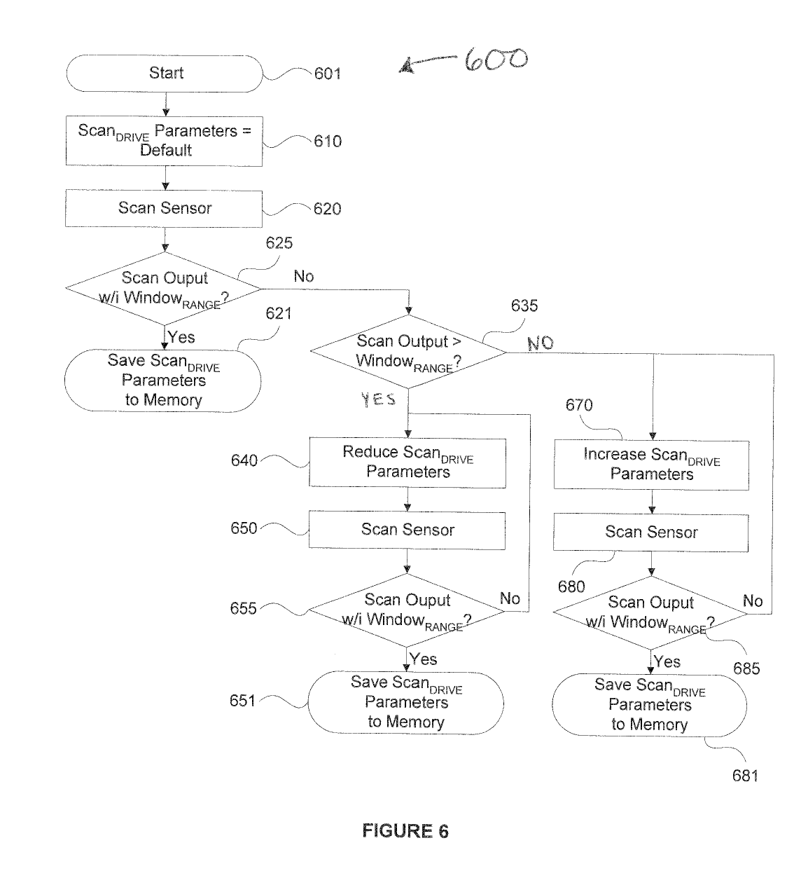

FIG. 6 illustrates a more detailed method 600 for tuning parameters that affect the output of capacitance to digital converter 110, 400 or 450. One method for adjusting the output of the capacitance sensor is to increase or decrease the drive parameters such as the switched capacitor frequency (in the case of charge transfer or sigma delta scanning methods) or IDAC output, offset or range (in the case of successive approximation or relaxation oscillator methods).

The process is started at block 601. The scan_{DRIVE} parameters are set to default values determined in development in block 610. The sensors are then scanned using the default parameters in block 620. The output of the scan is then compared to a window_{RANGE} of values in decision block 625. If the scan output is within the window_{RANGE}, the default parameters from block 610 are saved to memory 130 in block 621.

If the scan output is outside the scan output is outside the window_{RANGE}, it is then determined if the scan output is greater than the window_{RANGE} in decision block 635. If the scan output is greater than the window_{RANGE}, the scan_{DRIVE} parameters are adjusted to lower the scan output in block 640. The sensor is then scanned again in block 650 and the output is compared again the window_{RANGE} in decision block 655. If the output is within the range, the adjusted parameters are saved to memory 130 in block 651. If the output is outside the window_{RANGE}, the parameters are reduced again in block 640.

If, in decision block 635, the output is determined to not be greater than the window_{RANGE}, the scan_{DRIVE} parameters are increased to increase the output of the capacitance to digital converter 110 in block 670. The sensor is then scanned in block 680 and the output compared to the window_{RANGE} again in block 685. If the output is within the window_{RANGE}, the scan_{DRIVE} parameters are saved to memory 130 in block 681. If the output is outside the window_{RANGE} in block 683, the scan_{DRIVE} parameters are increased further in block 670 and the sensor is scanned again in block 680.

One embodiment of the change in Scan_{DRIVE} parameters is shown in FIG. 6, wherein the parameters are increased or decreased. This change can be by incrementing or decrementing the parameters. Other embodiments may use a linear step that is not incrementing or decrementing but changing by another value, a successive approximation of parameter values to bring the scan output within the Window_{RANGE}, or any other search method for calculating appropriate settings when comparing an output value compared to expected values.

The maximum value detected by the sensor is used to calculate the finger threshold. The method 700 for determining the maximum value is illustrated in FIG. 7. The method is started at block 701. The sensor is scanned as part of normal operation in block 710. The value S_{X} measured by the capacitance to digital converter on the sensor is compared to the maximum value S_{MAX}, which is the highest recorded output of the capacitance to digital converter in decision block 715. The maximum value S_{MAX} is used as the output in the methods of FIGS. 5 and 6. If S_{X} is greater than the maximum value S_{MAX}, S_{MAX} is set equal to the measured value S_{X} in block 720 and saved to memory 130 in block 751.

If the S_{X} is not greater than S_{MAX}, a variable Sample_{N} is incremented. The variable Sample_{N} is compared to a threshold value Sample_{MAX} in decision block 735.

If Sample_{N} is not greater than the threshold value Sample_{MAX}, the maximum value S_{MAX} is saved to memory 130 in block 751.

If Sample_{N} is greater than Sample_{MAX}, Sample_{N} is reset to “0” in block 740 and the value of Sample_{MAX} is compared to “0” in step 745. If Sample_{MAX} is 0, the maximum value S_{MAX} is saved to memory 130 in block 751. If Sample_{MAX} is greater than 0, Sample_{MAX} is decremented on block 750 and the maximum value S_{MAX} is saved to memory 130 in block 751.

The “Measure Noise” block (block 550, FIG. 5) is illustrated in the method 800 of

FIG. 8. The difference count, □countₙ for a sensor is measured by subtracting a previous measured count from the current measured count in block 810. The sign of the difference counts from two calculations compared in block 820. That is, if a first calculation has an output of 1000 and a second calculation has an output of 1100, the difference count is 100 (positive). If the first calculation has an output of 1100 and the second calculation has an output of 1000, the difference count is −100 (negative). If the sign of Xₙ is equal to the sign of Xₙ₋₁ from a previous scan in decision block 825, a variable Yₙ is set equal to 0 in block 830. If Xₙ is not equal to Xₙ₋₁, the variable Yₙ is set equal to Xₙ in block 840. The absolute value of Yₙ is calculated in block 850 and compared to a noise value Noiseₛ, which is the noise value of the signal from capacitance to digital converter 110, 400 or 450, in block 855. If Y_{abs} is equal to the value Noiseᵢ, then the Noiseᵢ variable is increased by 0.25. If Y_{abs} is less than the value Noiseᵢ, the Noiseᵢ variable is decreased by 0.02.

The “calculate thresholds” step (block 560, FIG. 5) uses the following equations.

The noise threshold, T_{N} is calculated from:

T_{A}=K1·N, (1)

where T_{N} is the noise threshold, K1 is the minimum acceptable signal to noise ratio (SNR) and N is the measured noise (from FIG. 8).

The signal threshold, T_{S} is calculated from:

T_{S}=K2·S_{MAX}, (2)

where T_{S} is the signal threshold for a finger or other conductive object on the sensor, K2 is the fraction of the recently observed change in capacitance that is due to a touch (typical value may be 0.5) and S_{MAX} is the highest detected signal on the sensor (from FIG. 7).

The minimum capacitance change detectable by the sensor s given by:

T_{MIN}=K3_{(pF)}, (3)

where T_{MIN} is the minimum detectable capacitance change and K3 is the setting (in picofarads) used for the minimum detectable capacitance change.

The finger threshold, T_{F} is the greatest of three values from equations 1, 2 and 3. The baseline adjust threshold, T_{BASE} is the greatest of the signal threshold, T_{S}, produced by a scale factor and the noise threshold, T_{N}. The hysteresis is the finger threshold, T_{F}, produced by a scale factor.

Embodiments of the present invention, described herein, include various operations. These operations may be performed by hardware components, software, firmware, or a combination thereof. As used herein, the term “coupled to” may mean coupled directly or indirectly through one or more intervening components. Any of the signals provided over various buses described herein may be time multiplexed with other signals and provided over one or more common buses. Additionally, the interconnection between circuit components or blocks may be shown as buses or as single signal lines. Each of the buses may alternatively be one or more single signal lines and each of the single signal lines may alternatively be buses.

Certain embodiments may be implemented as a computer program that may include instructions stored on a machine-readable medium. These instructions may be used to program a general-purpose or special-purpose processor to perform the described operations. A machine-readable medium includes any mechanism for storing or transmitting information in a form (e.g., software, processing application) readable by a machine (e.g., a computer). The machine-readable medium may include, but is not limited to, magnetic storage medium (e.g., floppy diskette); optical storage medium (e.g., CD-ROM); magneto-optical storage medium; read-only memory (ROM); random-access memory (RAM); erasable programmable memory (e.g., EPROM and EEPROM); flash memory; electrical, optical, acoustical, or other form of propagated signal (e.g., carrier waves, infrared signals, digital signals, etc.); or another type of medium suitable for storing electronic instructions.

Additionally, some embodiments may be practiced in distributed computing environments where the machine-readable medium is stored on and/or executed by more than one computer system. In addition, the information transferred between computer systems may either be pulled or pushed across the communication medium connecting the computer systems.

Some embodiments may be practiced during development. Parameters may be determined during development and programmed into the device during manufacturing. Other usage models may include determining and storing parameters to memory: as part of system test in manufacturing, on first power up, on every power up, periodically during normal operation of the sensing device, continuously during normal operation of the sensing device or on command from an external device or command.

Although the operations of the method(s) herein arc shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. An apparatus, comprising:
a controller coupled to a capacitance measurement device configured to convert capacitance to a digital value, wherein the conversion uses at least one configurable parameter, wherein the controller is configured to execute tuning logic, wherein the tuning logic is configured to alter the at least one configurable parameter.

2. The apparatus of claim 1, wherein the tuning logic is configured to define a first comparison for the digital value to first expected digital values and to alter the at least one configurable parameter in response to the first comparison.

3. The apparatus of claim 2, wherein the tuning logic is configured to define a second comparison for the digital value to second expected values based on the first comparison and to alter the at least one configurable parameter in response to the second comparison.

4. The apparatus of claim 1, wherein the capacitance measurement device has at least one input coupled to at least one capacitance sensor.

5. The apparatus of claim 1 wherein the controller is configured to execute the tuning logic on start up.

6. The apparatus of claim 1, wherein the controller is configured to execute the tuning logic periodically during operation of the capacitance measurement device.

7. The apparatus of claim 1, wherein the controller is configured to execute threshold logic which comprises:
noise threshold measurement logic;
finger detection threshold logic; and
threshold updated hysteresis logic.

8. A method comprising:
converting a capacitance of a capacitance sensor to a digital value, wherein the capacitance sensor is coupled to a capacitance measurement device;
comparing the digital value to a first expected value;
changing a first parameter of the capacitance measurement device based on the comparing of the digital value to the first expected value. modifying output of the capacitance measurement device based on the first parameter that is changed.

9. The method of claim 8, wherein the converting, the comparing, the changing and the modifying are repeated at least one time until the digital value is within an expected window.

10. The method of claim 8, further comprising:
comparing the digital value to a second expected value;
changing a second parameter based on the comparing of the digital value to the second expected value.

11. The method of claim 8, wherein the at least one parameter is a drive strength on the capacitance sensor.

12. The method of claim 8, wherein the first parameter is a resolution of a capacitance to digital conversion circuit configured to convert the capacitance of the capacitance sensor to a digital value.

13. The method of claim 8, further comprising calculating a baseline value from the digital value and a previously measured digital value, wherein the baseline value is a representation of the capacitance of the capacitance sensor with no conductive object in proximity to the capacitance sensor.

14. The method of claim 8, further comprising calculating a baseline value from, the digital value and an expected digital value.

15. The method of claim 6 further comprising:
calculating a baseline digital value, wherein the baseline value is a representation of the capacitance of the capacitance sensor with no conductive object in proximity to the capacitance sensor;
calculating a noise level; and
calculating at least one threshold.

16. The method of claim 14, wherein the calculating a noise level comprises:
measuring a difference between a first scan and a second scan of the capacitance sensor; and
calculating an absolute value of the difference between the first scan and the second scan of the capacitance sensor.

17. The method of claim 14, wherein the calculating the at least one threshold comprises calculating a finger detection threshold for the capacitance sensor.

18. The method of claim 14, wherein the calculating the at least one threshold comprises calculating a noise threshold for the capacitance sensor.

19. The method of claim 12 wherein at the comparing is executed periodically during normal operation of the capacitance measurement device.

20. A system comprising:
at least one capacitance sensor;
a capacitance measurement device coupled to the at least one capacitance sensor, wherein said capacitance measurement device comprises:
a capacitance to digital converter coupled to the at least one capacitance sensor,
a controller coupled to the capacitance to digital converter,
a memory coupled to the controller and configured to store programs, the programs executable by the controller,
wherein the programs include:
tuning logic,
baseline offset filter logic, and
threshold calculation logic.

21. The system of claim 17, wherein the threshold calculation logic comprises:
noise threshold calculation logic; and
finger detection threshold calculation logic;

22. The system of claim 17, wherein the tuning logic comprises:
range comparison and adjustment logic; and
resolution comparison and adjustment logic.

23. The system of claim 17, wherein the at least one capacitance sensor is a plurality of sensors, the plurality of sensors configured to be coupled to the capacitance to digital converter individually or in unison.

24. A system comprising:
means for converting measured capacitance to a digital value with a capacitance to digital converter; and
means for adjusting a range, a resolution, a baseline offset and at least one of a plurality of thresholds of a capacitance sensor according to a logic executed by a controller.
